(19) United States
(12) Patent Application Publication
(10) Pub. No.: US 2020/0181755 A1
(43) Pub. Date: Jun. 11, 2020

(54) VAPOR DEPOSITION MASK, VAPOR DEPOSITION APPARATUS, VAPOR DEPOSITION MASK PRODUCTION METHOD, AND ELECTROLUMINESCENT DISPLAY APPARATUS PRODUCTION METHOD

(71) Applicant: Sharp Kabushiki Kaisha, Sakai City, Osaka (JP)

(72) Inventors: Yuhki KOBAYASHI, Sakai City (JP); Shinichi KAWATO, Sakai City (JP); Satoshi INOUE, Sakai City (JP)

(21) Appl. No.: 16/349,312

(22) PCT Filed: Nov. 15, 2016
(86) PCT No.: PCT/JP2016/083773

§ 371 Date: May 13, 2019

(51) Int. Cl. C23C 14/04; C23C 14/24; H01L 51/00; H01L 51/56

(52) U.S. Cl. CPC C23C 14/042; C23C 14/24; H01L 51/5012; H01L 51/56; H01L 51/001; H01L 51/0011

(57) ABSTRACT

A vapor deposition mask includes, in a layered manner: a metal mask including at least one metal mask opening; and a resin mask including a plurality of resin mask openings. The resin mask openings are arranged at least one in a Y-axial direction. The resin mask openings exposed from the metal mask opening and aligned in the Y-axial direction in the respective positions in an X-axial direction have such total opening lengths in the Y-axial direction as to increase from the center in the X-axial direction toward both end portions in the X-axial direction.

### TECHNICAL FIELD

The disclosure relates to a vapor deposition mask, a vapor deposition apparatus, a manufacturing method for a vapor deposition mask, and a manufacturing method for an electroluminescence display device.

### BACKGROUND ART

In recent years, flat panel displays have been utilized in various products and fields, and there are demands for flat panel displays having even larger sizes, even higher picture quality, and even lower power consumption.

In view of such circumstances, Electro luminescence (referred to as EL below) display devices including EL elements utilizing the electroluminescence of organic or inorganic materials are attracting much attention as flat panel displays due to their excellent qualities, such as low voltage driving, high responsiveness, and self-luminosity, while being in a completely solid state.

In order to enable full color display, EL display devices include light emitting layers that emit light of a desired color corresponding to a plurality of subpixels constituting a pixel.

For example, the vacuum vapor deposition technique using a vapor deposition mask referred to as a shadow mask is used for patterning and forming the light emitting layers.

In order to enable a high-definition EL display device, vapor deposition of vapor deposition particles is carried out with high accuracy on a film target substrate, so it is necessary to form high accuracy openings in the vapor deposition mask.

A metal mask that is prepared by processing a mask base material made from a metal plate and that includes openings in a given pattern is typically used as a vapor deposition mask in the related art. A vapor deposition mask is normally used fixed to a mask frame.

However, with the existing metal processing technology, it may be difficult to form the openings in the metal plate with accuracy. Also, when the metal mask is used as the vapor deposition mask, it may be difficult to form a high definition vapor deposition film pattern due to the effect of positional offset, warping, and the like, resulting from thermal expansion of the metal plate.

Particularly, in recent years in the field of EL display devices, as in the field of liquid crystal display devices, an increase in the number of pixels per inch (ppi) in the display device is demanded for even higher picture quality. However, in using a selectively patterning vapor deposition method with a metal mask, there is a limit to the processing accuracy of a metal mask, in other words, the positional accuracy of the openings themselves in the metal mask, and the opening pattern accuracy. Therefore, it may be difficult to form a high definition vapor deposition film suitable for 300 ppi or higher on a substrate.

Also, when a vapor deposition mask made from metal only is used as the vapor deposition mask, the mass increases as the vapor deposition mask becomes larger, and the total mass including support bodies such as the mask frame and the like increases, which may cause difficulties in handling.

Thus, a compound vapor deposition mask using resin as part of the mask base material constituting the vapor deposition mask has recently been proposed to reduce the weight and increase the accuracy of the openings (for example, see PTL 1).

On the other hand, as a large substrate film formation technique using a large substrate as a film target substrate, a scan vapor deposition technique that does not require a vapor deposition mask or a vapor deposition source having a size equivalent to that of the large film target substrate is receiving attention (for example, see PTL 2).

The scan vapor deposition technique uses a vapor deposition mask and a vapor deposition source (vapor deposition particle emission device) smaller than the film target substrate, and at least one of the film target substrate and a vapor deposition unit including the vapor deposition mask and the vapor deposition source is moved relative to the other, thereby performing scan film formation that is to form a film while scanning the film target substrate.

### CITATION LIST

### Patent Literature

PTL 1: JP 2013-165060 A (published on Aug. 22, 2013)

PTL 2: JP 2011-140717 A (published on Jul. 21, 2011)

### SUMMARY

### Technical Problem

However, vapor deposition particles emitted from a vapor deposition source opening of the vapor deposition source disperse with a certain distribution in amount. Typically, the amount immediately above the vapor deposition source opening has a maximum value, and the value decreases with a distance from the vapor deposition source opening in a plan view.

Thus, when the scan vapor deposition is performed in this state as it is, difference in light emission luminance due to the film thickness of the vapor deposition film causes a light emission failure, such as uneven light emission in a streaked manner.

Let θ represent the dispersion angle of the vapor deposition particles in a desired position x in a direction orthogonal to the relative movement direction of the film target substrate in the scan vapor deposition technique, and the film thickness of the vapor deposition film in the position x has an approximate distribution obtained by multiplying the cosine law (cos θ) by an exponent coefficient N.

For example, PTL 2 describes that a patterning slit (mask opening) at the central portion of a patterning slit sheet used as a vapor deposition mask is formed through etching to have a length (total opening length) shorter than the length (total opening length) of patterning slits at both end portions of the patterning slit sheet, thereby limiting an error in the uniformity of a vapor deposition film formed on a film target substrate within a range from 1 to 2%.

In the case of a metal mask, for example, by changing the total opening lengths of mask openings depending on the position in the direction orthogonal to the relative movement direction of a film target substrate in this way, the film thickness distribution can be corrected so that the formed vapor deposition film has uniform film thickness.

However, in the case of a compound vapor deposition mask, all mask openings are formed in a resin mask at once with a laser. Thus, the film thickness distribution cannot be corrected by changing the total opening lengths of the mask openings in the relative movement direction of the resin mask depending on the position in the direction orthogonal to the relative movement direction as described above or by changing the number of the mask openings in the resin mask in the relative movement direction.

In light of the above described problem, an object of the disclosure is to provide a compound vapor deposition mask with which film thickness can be readily corrected and a vapor deposition film having high definition and uniform film thickness can be formed, a vapor deposition apparatus, a manufacturing method for a vapor deposition mask, and a manufacturing method for an electroluminescence display device.

### Solution to Problem

To solve the above described problem, a vapor deposition mask according to one aspect of the disclosure includes: a metal mask; and a resin mask, the metal mask and the resin mask being layered. The metal mask includes at least one first opening. The at least one first opening has an opening length in a first direction, the opening length increasing from a center in a second direction toward both end portions in the second direction, the second direction being orthogonal to the first direction. The resin mask includes a plurality of second openings. The plurality of second openings are arranged at least one in the first direction and more than one in the second direction. The second openings exposed from the at least one first opening and aligned in the first direction in respective positions in the second direction have total opening lengths in the first direction, the total opening lengths increasing from the center in the second direction toward both end portions in the second direction.

To solve the above described problem, a vapor deposition apparatus according to one aspect of the disclosure is configured to form a vapor deposition film on a film target substrate, the vapor deposition film having a striped pattern. The vapor deposition apparatus includes a vapor deposition unit including: the vapor deposition mask according to one aspect of the disclosure; and a vapor deposition source including at least one vapor deposition source opening configured to emit vapor deposition particles, the vapor deposition source being disposed on a side opposite to a side having the film target substrate while interposing the vapor deposition mask between the vapor deposition source and the film target substrate. The vapor deposition mask has a length in a first direction shorter than a length of the film target substrate in the first direction. The vapor deposition film is formed on the film target substrate by moving at least one of the film target substrate and the vapor deposition unit in the first direction relative to the other.

To solve the above described problem, a manufacturing method for a vapor deposition mask according to one aspect of the disclosure, the vapor deposition mask including a metal mask and a resin mask in a layered manner, the metal mask including at least one first opening, the resin mask including a plurality of second openings, the plurality of second openings being arranged at least one in a first direction and more than one in a second direction, the second openings exposed from the at least one first opening and aligned in the first direction in respective positions in the second direction having total opening lengths in the first direction, the total opening lengths increasing from a center in the second direction toward both end portions in the second direction, includes: a first opening forming step of forming at least one first opening in a metal plate provided with a resin film on one of main surfaces of the metal plate, the at least one first opening penetrating only the metal plate; and a second opening forming step of forming a plurality of second openings in the resin film, the plurality of second openings penetrating only the resin film. The first opening forming step includes forming the at least one first opening having an opening length in the first direction, the opening length increasing from the center in the second direction toward both end portions in the second direction, the second direction being orthogonal to the first direction. The second opening forming step includes forming the plurality of second openings in the resin film from a side having the resin film, the plurality of second opening portions being arranged at least one in the first direction and more than one in the second direction orthogonal to the first direction.

To solve the above described problem, in a manufacturing method for an electroluminescence display device according to one aspect of the disclosure, the vapor deposition film constitutes a light-emitting layer of the electroluminescence display device, the film target substrate constitutes an electrode substrate of the electroluminescence display device, and the light-emitting layer is formed as a film on the electrode substrate by using the vapor deposition apparatus according to one aspect of the disclosure.

### Advantageous Effects of Disclosure

One aspect of the disclosure can provide a compound vapor deposition mask with which film thickness can be readily corrected and a vapor deposition film having high definition and uniform film thickness can be formed, a vapor deposition apparatus, a manufacturing method for a vapor deposition mask, and a manufacturing method for an electroluminescence display device.

### BRIEF DESCRIPTION OF DRAWINGS

FIG. 1 is a bottom view illustrating a schematic configuration of main portions of a vapor deposition mask, when viewed from a metal mask side, according to a first embodiment of the disclosure, together with the film thickness distribution of a vapor deposition film formed using the vapor deposition mask.

FIG. 2A is a bottom view illustrating a schematic configuration of the vapor deposition mask, when viewed from the metal mask side, according to the first embodiment of the disclosure, and FIG. 2B is a top view illustrating a schematic configuration of the vapor deposition mask, when viewed from a resin mask side, according to the first embodiment of the disclosure, together with other constituent elements of a vapor deposition apparatus according to the first embodiment of the disclosure.

FIG. 3 is an exploded perspective view illustrating a schematic configuration of the vapor deposition mask according to the first embodiment of the disclosure.

FIG. 4 is a cross-sectional view illustrating an example of a schematic configuration of main portions of the vapor deposition apparatus including the vapor deposition mask according to the first embodiment of the disclosure, together with a film target substrate.

FIGS. 5A to 5E are cross-sectional views illustrating steps, in order, of an example of a manufacturing method for the vapor deposition mask according to the first embodiment of the disclosure.

FIG. 6 is a bottom view illustrating a schematic configuration of main portions of another vapor deposition mask, when viewed from a metal mask side, according to the first embodiment of the disclosure, together with the film thickness distribution of a vapor deposition film formed using the vapor deposition mask.

FIG. 7 is a bottom view illustrating a schematic configuration of main portions of a vapor deposition mask for comparison including a metal mask, together with the film thickness distribution of a vapor deposition film formed using the vapor deposition mask for comparison.

FIG. 8 is a bottom view illustrating a schematic configuration of main portions of a vapor deposition mask, when viewed from a metal mask side, according to Modified Example 1 of the first embodiment of the disclosure, together with the film thickness distribution of a vapor deposition film formed using the vapor deposition mask.

FIGS. 9A to 9E are bottom views each illustrating an example of a schematic configuration of main portions of a vapor deposition mask, when viewed from a metal mask side, according to Modified Example 2 of the first embodiment of the disclosure.

FIG. 10 is a top view illustrating a schematic configuration of a vapor deposition mask, when viewed from a resin mask side, according to a second embodiment of the disclosure, together with other constituent elements of a vapor deposition apparatus according to the second embodiment of the disclosure.

### DESCRIPTION OF EMBODIMENTS

Hereinafter, embodiments of the disclosure will be described in detail.

### First Embodiment

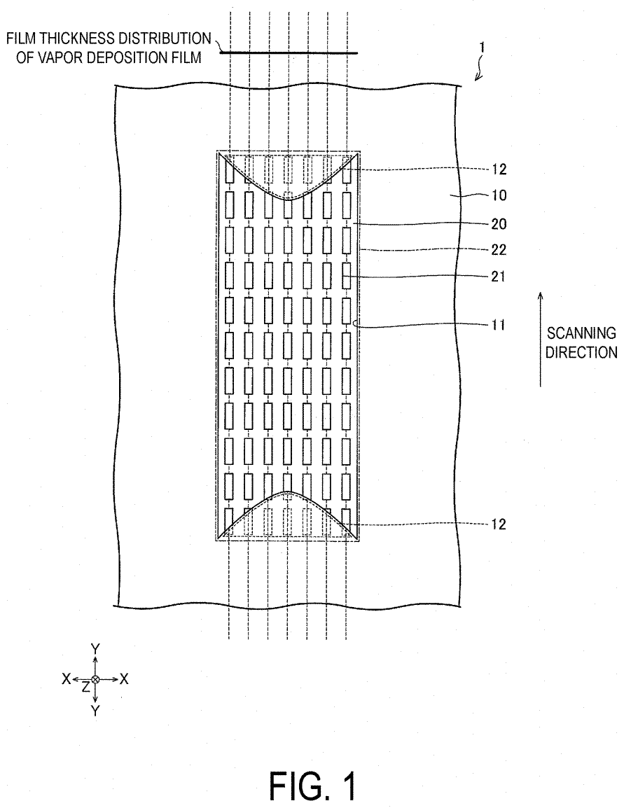

One embodiment of the disclosure will be described below with reference to FIG. 1 to FIGS. 9A to 9E.

Note that, hereinafter, a horizontal direction axis along a direction orthogonal to a scanning direction of a film target substrate and a direction orthogonal to a normal direction of a film target surface (vapor deposited surface) of the film target substrate and parallel to the scanning direction of the film target substrate are referred to as a Y-axial direction (first direction). A horizontal direction axis along the scanning direction of the film target substrate and a direction orthogonal to the normal direction of the film target surface of the film target substrate and the scanning direction of the film target surface (in other words, orthogonal to the Y-axis) are referred to as an X-axial direction (second direction). The normal direction of the film target surface of the film target substrate and a direction orthogonal to the X-axis and the Y-axis being an extending direction of a vapor deposition axis line orthogonal to the film target surface (i.e., an up-down direction orthogonal to a horizontal plane) are referred to as a Z-axial direction (third direction).

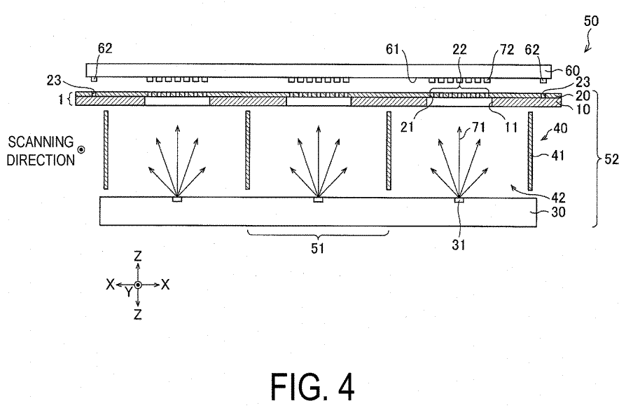

For convenience of description, unless otherwise stated, the side indicated by the upward arrow in the Z-axial direction illustrated in FIG. 4 is an upper side.

A vapor deposition mask according to the present embodiment is a vapor deposition mask for scan vapor deposition. Scan vapor deposition uses a vapor deposition mask smaller than a film target substrate (in specific, a vapor deposition mask having a length in the scanning direction shorter than the length of the film target substrate in the scanning direction), and performs vapor deposition to the film target substrate while scanning the film target substrate.

First, an example of a vapor deposition apparatus for scan vapor deposition including the vapor deposition mask according to the present embodiment will be described below with reference to FIG. 4.

### Schematic Configuration of Vapor Deposition Apparatus

FIG. 4 is a cross-sectional view illustrating an example of a schematic configuration of main portions of the vapor deposition apparatus 50 including the vapor deposition mask 1 according to the present embodiment, together with a film target substrate 60. Note that, in FIG. 4, the number of openings, which will be described later, is reduced for convenience of illustration.

The vapor deposition apparatus 50 according to the present embodiment includes a film formation chamber (vacuum chamber) (not illustrated), and, as illustrated in FIG. 4, also includes a vapor deposition unit 52 including at least a vapor deposition source 30 being a supply source of vapor deposition particles 71 and the vapor deposition mask 1, in the film formation chamber. Note that, as illustrated in FIG. 4, the vapor deposition unit 52 preferably further includes a limiting plate unit 40 disposed between the vapor deposition source 30 and the vapor deposition mask 1 and limiting the passage angles (flow) of the vapor deposition particles 71 emitted from the vapor deposition source 30.

The vapor deposition source 30, the limiting plate unit 40, the vapor deposition mask 1, and the film target substrate 60 are arranged in this order from the vapor deposition source 30 side in the film formation chamber (not illustrated) while facing each other with certain gaps therebetween (i.e., away from each other by certain distances) in the Z-axial direction.

The vapor deposition source 30, the limiting plate unit 40, and the vapor deposition mask 1 are placed in positions fixed with respect to each other and are thus formed into a unit as the vapor deposition unit 52. The vapor deposition source 30, the limiting plate unit 40, and the vapor deposition mask 1 may be integrated by, for example, being held by the same holding member, or may be held independently of each other and perform control actions as a single unit.

The vapor deposition apparatus 50 further includes a film target substrate holding member (not illustrated) holding the film target substrate 60, and at least one of a transport device (film target substrate transport device) transporting the film target substrate 60 and a transport device (vapor deposition unit transport device) transporting the vapor deposition unit 52.

The transport device moves at least one of the film target substrate 60 and the vapor deposition unit 52 relative to the other in the Y-axial direction being the scanning direction, thereby, in the end, forming a vapor deposition film 72 in the entire film formed region of the film target substrate 60.

As illustrated in FIG. 4, the film target substrate 60 is provided with at least two alignment markers 62 (that is, a total of four or more with one at at least each of corners of the film target substrate 60) for positioning (alignment) between the film target substrate 60 and the vapor deposition mask 1 by correcting a shift in position between the film target substrate 60 and the vapor deposition mask 1 in the X-axial direction and the Y-axial direction and a shift in position between the film target substrate 60 and the vapor deposition mask 1 in the rotation direction (i.e., a shift in the rotation direction in the XY plane (θ shift)).

The alignment markers 62 are disposed outside a vapor deposition region in the scanning direction of the film target substrate 60 (in other words, in the relative movement direction of the film target substrate 60 and the vapor deposition unit 52).

Note that, when, for example, the film target substrate 60 is an electrode substrate (specifically, a TFT substrate) for forming a light-emitting layer as a film used in, for example, an organic EL display device, the alignment markers 62 may be made from the same material as the electrode material used in the electrode substrate. Thus, the alignment markers 62 may be formed from the same material as that of, for example, a gate electrode, a source electrode, a drain electrode, and the like in the film target substrate 60, such as a TFT substrate, together with these electrodes in a step of forming these electrodes.

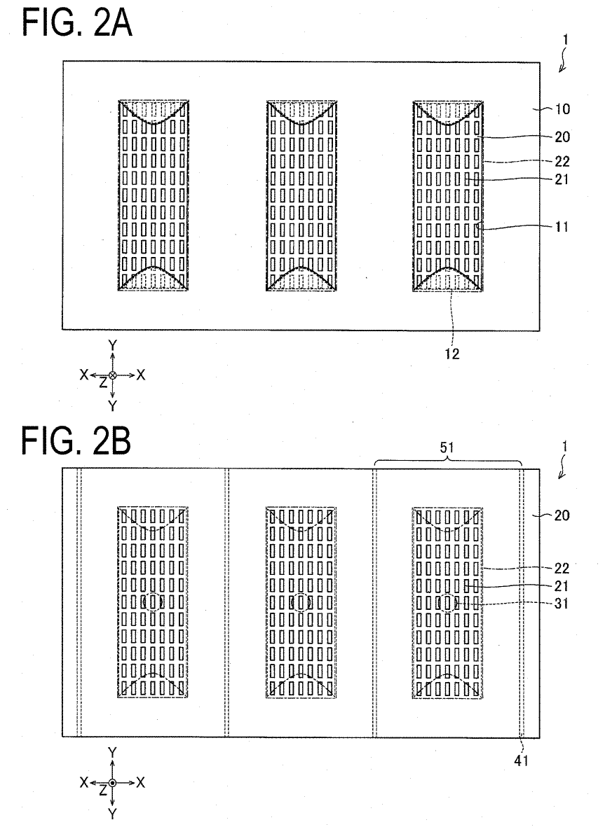

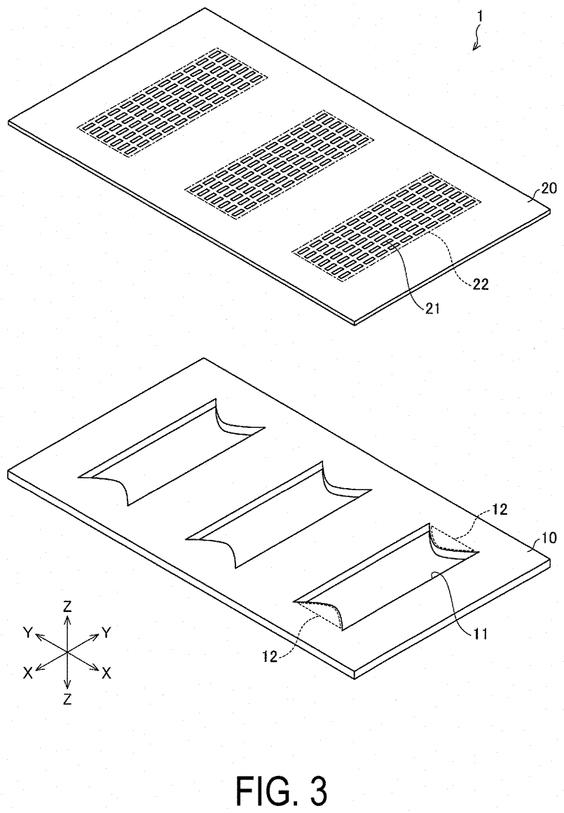

On the other hand, as illustrated in FIG. 4, the vapor deposition mask 1 is provided with at least two alignment markers 23 (preferably, a total of four or more with one at at least each of corners of the vapor deposition mask 1) for positioning (alignment) between the film target substrate 60 and the vapor deposition mask 1 by correcting the above-described shifts in position between the film target substrate 60 and the vapor deposition mask 1. With the alignment markers 23 provided in plurality to the vapor deposition mask 1, the vapor deposition mask 1 and the film target substrate 60 can be positioned even in the horizontal direction. Note that, in FIG. 2A, FIG. 2B, and FIG. 3, the alignment markers 23 are omitted.

The alignment markers 23 are disposed in positions corresponding to the outside of the vapor deposition region of the film target substrate 60 (in specific, the outside of a plurality of vapor deposition blocks 51 as illustrated in FIG. 4) along the short side of the vapor deposition mask 1, that is, in the relative movement direction, while facing the alignment markers 62.

The alignment markers 23 are constituted by, for example, openings. Note that these openings include notches.

The shapes and sizes of the alignment markers 23 and 62 are not particularly limited, and desired shapes and sizes can be determined.

A method of alignment between the film target substrate 60 and the vapor deposition mask 1 with the alignment markers 23 and 62 including a method of detecting positions of the alignment markers 23 and 62 is not particularly limited, and a method in the related art can be employed. As the method of detecting positions of the alignment markers 23 and 62, various known methods in the related art can be employed that include a method of detecting an image with an image sensor, a method of detecting intensity of reflection of laser light, infrared light, or the like with an optical sensor, such as a position sensor, an LED alignment sensor, or a detector, measuring the position of an object to be detected by measuring the position of a beam, and the like.

The alignment between the vapor deposition mask 1 and the film target substrate 60 is desirably performed while the film target substrate 60 is scanned. However, the alignment may be appropriately performed before the film target substrate 60 is scanned, and the alignment may not be performed while the film target substrate 60 is scanned.

The vapor deposition source 30 serves as a container that holds vapor deposition material within. The vapor deposition source 30 may be a container that directly contains vapor deposition material in the interior of the container, or may be formed having a load-lock type tube so that the vapor deposition material can be supplied from outside.

In a surface, facing the vapor deposition mask 1 and the limiting plate unit 40, of the vapor deposition source 30, a plurality of vapor deposition source openings 31 (emission openings) emitting the vapor deposition particles 71 are arranged, as openings, with certain intervals therebetween in the X-axial direction orthogonal to the scanning direction.

However, the present embodiment is not limited to this configuration. Depending on the size of the film target substrate 60, a single vapor deposition source 30 provided with a single vapor deposition source opening 31 may be used, or a plurality of vapor deposition sources 30 each provided with a single vapor deposition source opening 31 may be arranged in the X-axial direction.

The vapor deposition source 30 is disposed on the side opposite to the side having the film target substrate 60 with the vapor deposition mask 1 interposed therebetween, and is preferably disposed facing the vapor deposition mask 1 with the limiting plate unit 40 interposed therebetween. The vapor deposition source 30 heats the vapor deposition material to be evaporated (in a case where the vapor deposition material is a liquid material) or sublimated (in a case where the vapor deposition material is a solid material) to generate gaseous vapor deposition particles 71. The vapor deposition source 30 emits the vapor deposition material gasified in this way from the vapor deposition source openings 31 toward the limiting plate unit 40 and the vapor deposition mask 1, as the vapor deposition particles 71.

The limiting plate unit 40 includes a plurality of limiting plates 41 arranged away from each other in the X-axial direction and parallel to each other. Thus, limiting plate openings 42 are defined between the limiting plates 41 adjacent to each other in the X-axial direction, as openings.

Note that, although not illustrated, the limiting plate unit 40 may have a configuration in which the limiting plates 41 are fixed to a holding body member connecting and holding the limiting plates 41, with screws, by welding, or the like. Alternatively, the limiting plate unit 40 may be a block-like unit having a configuration in which the limiting plates 41 are formed between adjacent limiting plate openings 42 on a single rectangular plate having the XY plane as the main surface and a major axis extending in the X-axial direction by defining the limiting plate openings 42 with certain intervals therebetween in the X-axial direction.

The limiting plate unit 40 divides, with the limiting plates 41, a space between the vapor deposition mask 1 and the vapor deposition source 30 into a plurality of vapor deposition spaces constituted by the limiting plate openings 42. In the vapor deposition mask 1, metal mask openings 11 and resin mask openings 21 are formed as openings (first openings). Note that a configuration of the vapor deposition mask 1 will be described in detail later.

A pair of limiting plates 41 adjacent to each other in the X-axial direction, the vapor deposition source opening 31 located between the pair of limiting plates 41, and the metal mask opening 11 and the resin mask openings 21 located between the pair of limiting plate 41 constitute one vapor deposition block 51. The vapor deposition unit 52 according to the present embodiment includes the vapor deposition blocks 51 arranged in the X-axial direction. The vapor deposition blocks 51 have the same configuration.

As illustrated in FIG. 4, each of the limiting plate openings 42, each of the vapor deposition source openings 31, and each of the metal mask openings 11 are in a one-to-one relationship, and are formed so that the intervals of the openings in the X-axial direction (i.e., the distance between the centers of adjacent limiting plate openings 42, the distance between the centers of adjacent vapor deposition source openings 31, and the distance between the centers of adjacent metal mask openings 11) are equal to each other. Thus, one emission opening and one metal mask opening 11 are arranged in one vapor deposition block 51, in other words, between the pair of limiting plates 41 adjacent to each other in the X-axial direction.

Each of the vapor deposition source openings 31 is arranged in correspondence with each of the limiting plate openings 42 and the metal mask openings 11. Each of the vapor deposition source openings 31 is located, for example, in a center of the corresponding limiting plate opening 42 and in a center of the corresponding metal mask opening 11 in at least the X-axial direction (desirably, in the X-axial direction and the Y-axial direction as illustrated in FIG. 2B) in a plan view.

On the other hand, the limiting plate openings 42, the vapor deposition source openings 31, and the metal mask openings 11 have the intervals greater than the intervals of the resin mask openings 21. The plurality of resin mask openings 21 are arranged between the pair of limiting plates 41 adjacent to each other in the X-axial direction.

As illustrated in FIG. 4, the vapor deposition particles 71 emitted from the vapor deposition source openings 31 spread substantially isotropically for a time. Then, the vapor deposition particles 71 pass by the limiting plate openings 42, so that, while the angles of incidence on the metal mask openings 11 and the resin mask openings 21 are limited, the vapor deposition particles 71 reach the vapor deposition mask 1. The vapor deposition particles 71 passing through the metal mask openings 11 and the resin mask openings 21 adhere to the film target substrate 60, thereby forming the vapor deposition film 72 having a pattern corresponding to the resin mask openings 21 on a film target surface 61 of the film target substrate 60.

At this time, the vapor deposition particles 71 emitted from the vapor deposition source opening located diagonally below, also reach each of the limiting plate openings 42 and each of the metal mask openings 11. However, most of the vapor deposition particles 71 are emitted from the vapor deposition source opening 31 located immediately below. FIG. 4 illustrates the flow of the vapor deposition particles 71 emitted from each of the vapor deposition source openings 31 conceptually by using arrows. The length of each of the arrows indicates the number of the vapor deposition particles 71.

As illustrated in FIG. 4, the vapor deposition particles 71 emitted from each of the vapor deposition source openings 31 disperse with a certain distribution in amount. As illustrated with the arrows in FIG. 4, concerning the dispersion of the vapor deposition particles 71 emitted from each of the vapor deposition source openings 31, typically, the amount immediately above the vapor deposition source opening 31 has a maximum value, and the value decreases with a distance from the vapor deposition source opening 31 in a plan view.

Thus, when a resin mask opening 21 located immediately above the vapor deposition source opening 31 has the same total opening length in the Y-axial direction as that of a resin mask opening 21 located remotely from the position immediately above the vapor deposition source opening 31, a portion, formed through a resin mask opening 21 farther away from the position immediately above the vapor deposition source opening 31, of the vapor deposition film 72 formed with the vapor deposition source opening 31 in each of the vapor deposition blocks 51 has a thinner film thickness in accordance with the N-value of the vapor deposition source opening 31 (nozzle).

In other words, when a resin mask opening 21 located in a center of each of the vapor deposition blocks 51 in the X-axial direction has the same total opening length in the Y-axial direction as that of a resin mask opening 21 arranged remotely in the X-axial direction from the resin mask opening 21 located in the center in the X-axial direction (e.g., arranged at either one of end portions in the X-axial direction of each of the vapor deposition blocks 51), a portion, formed through the resin mask opening 21 farther away in the X-axial direction from the resin mask opening 21 located in the center in the X-axial direction, of the vapor deposition film 72 has a thinner film thickness. The vapor deposition film 72 having such nonuniform film thickness causes uneven light emission. Specifically, the light emission luminance differs depending on the film thickness of the vapor deposition film 72, causing a failure, such as uneven light emission in a streaked manner in the organic EL display device.

### Outline Configuration of Vapor Deposition Mask 1

The vapor deposition mask 1 according to the present embodiment has a configuration described below. FIG. 1 is a bottom view illustrating a schematic configuration of main portions of the vapor deposition mask 1, when viewed from the metal mask 10 side, according to the present embodiment, together with the film thickness distribution of a vapor deposition film formed using the vapor deposition mask 1. FIG. 2A is a bottom view illustrating a schematic configuration of the vapor deposition mask 1, when viewed from the metal mask 10 side along the Z-axis, according to the present embodiment, and FIG. 2B is a top view illustrating a schematic configuration of the vapor deposition mask 1, when viewed from the resin mask 20 side along the Z-axis, according to the present embodiment, together with other constituent elements of the vapor deposition apparatus 50 according to the present embodiment. In other words, FIG. 2B is a top view illustrating an example of a schematic configuration of main portions of the vapor deposition apparatus 50 according to the present embodiment. Note that FIG. 2B is illustrated as a see-through view enabling recognition of relative position relationship among the vapor deposition source openings 31 and the limiting plates 41, the metal mask openings 11 provided to the metal mask 10, and a group of the resin mask openings 21 (hereinafter referred to as a “resin mask opening group 22”) provided to the resin mask 20. FIG. 3 is an exploded perspective view illustrating a schematic configuration of the vapor deposition mask 1 according to the present embodiment. Note that, similar to FIG. 4, the numbers of the metal mask openings 11 and the resin mask openings 21 being openings are reduced for convenience of illustration in FIG. 1 to FIG. 3.

As described above, the vapor deposition mask 1 according to the present embodiment is a vapor deposition mask for scan vapor deposition and is shaped into a rectangle having a length in the Y-axial direction shorter than the length of the film target substrate 60 in the Y-axial direction.

The vapor deposition mask 1 is suitably used in manufacturing an EL display device, such as an organic EL display device, requiring high definition separately patterning vapor deposition. The vapor deposition film 72 formed using the vapor deposition mask 1 is used as, for example, an organic film, such as a light-emitting layer of an organic EL display device. Note that the following description exemplifies a case in which the vapor deposition apparatus 50 including the vapor deposition mask 1 is an organic EL display device manufacturing apparatus, the film target substrate 60 is an electrode substrate (specifically, a TFT substrate) for forming a light-emitting layer as a film used in an organic EL display device, and the vapor deposition film 72 formed using the vapor deposition mask 1 is a light-emitting layer (organic layer) of an organic EL display device. However, the present embodiment is not limited to this case, and obviously, the vapor deposition mask 1 and the vapor deposition apparatus 50 can be used in any case of forming a vapor deposition film 72 having a striped pattern by scan vapor deposition.

The film target substrate 60 may be an electrode substrate, such as a TFT substrate, in a single EL display device, or may be a mother substrate from which a plurality of EL display devices can be cut out (i.e., a large electrode substrate provided with a plurality of circuits corresponding to a plurality of electrode substrates in a plurality of EL display devices). In a mass manufacturing process, a plurality of EL display devices are formed on the mother substrate, and the mother substrate is divided into individual EL display devices.

As illustrated in FIG. 1 to FIG. 4, the vapor deposition mask 1 according to the present embodiment is a compound vapor deposition mask (Fine Hybrid Mask (FHM)) including the metal mask 10 and the resin mask 20 in a layered manner.

### Metal Mask 10

The metal mask 10 is provided with at least one metal mask opening 11 as a penetrating hole (opening) for forming a vapor deposition film, that penetrates the metal mask 10 in the Z-axial direction and transmits the vapor deposition particles 71. FIGS. 2A and 2B to FIG. 4 illustrate an example of a case in which the metal mask 10 is provided with a plurality of (for example, three) metal mask openings 11 in the X-axial direction.

As illustrated in FIG. 1 to FIG. 3, each of the metal mask openings 11 is formed to be longer in the Y-axial direction than in the X-axial direction, and to have such an opening length in the Y-axial direction as to increase continuously from the center in the X-axial direction toward both end portions in the X-axial direction in a symmetrical manner with respect to the center in the X-axial direction in consideration of the film thickness distribution of the vapor deposition film 72 in the relative movement direction (Y-axial direction) of the film target substrate 60. Thus, each of the metal mask openings 11 is shaped into a rectangle in which both end portions in the Y-axial direction have a two-forked shape having curvature. In other words, each of the metal mask openings 11 has a shape deformed so that both end portions of the rectangular opening in the Y-axial direction have a two-forked shape having curvature.

Thus, the metal mask 10 is provided with metal remaining portions 12 that are disposed at both end portions of each of the metal mask openings 11 in the Y-axial direction, are constituted by metal portions remaining without being cut out (i.e., being opened) into rectangular shapes, and protrude from both end portions in the X-axial direction of both end portions of each of the metal mask openings 11 in the Y-axial direction (i.e., the four corners of each of the metal mask openings 11) toward the center in the Y-axial direction. Each of the metal remaining portions 12 has a curved tapered shape having curvature. By providing the metal remaining portions 12, each of the metal mask openings 11 has a continuously varying opening length in the Y-axial direction.

Note that the opening width of each of the metal mask openings 11 in the X-axial direction is not particularly limited. In the vapor deposition mask 1 illustrated in FIG. 1 to FIG. 4, for example, organic film patterns for three organic EL display devices are formed in correspondence with the three metal mask openings 11, and each of the metal mask openings 11 is formed, for example, in conformance to the width of a display region of a TFT substrate of one organic EL display device.

Furthermore, the opening length of each of the metal mask openings 11 in the Y-axial direction is not particularly limited. The opening length of each of the metal mask openings 11 in the Y-axial direction is determined appropriately for the film formation rate of the vapor deposition source openings 31 of the vapor deposition source 30 so that a vapor deposition film 72 having a desired film thickness is formed on the film target substrate 60 by scan vapor deposition. Note that, hereinafter, even when a direction is not particularly specified, the opening length indicates the length of the opening in the Y-axial direction, and the opening width indicates the length of the opening in the X-axial direction.

The metal mask 10 may be made from metal material similar to the material of a metal mask used in a vapor deposition mask in the related art, for example, stainless steel, iron-nickel alloy, aluminum alloy, invar material (iron-nickel alloy), or the like. Among these, invar material, which has a low coefficient of linear expansion and deforms very little when heated, is particularly suitable. Furthermore, the vapor deposition mask 1 or a mask holder (not illustrated) holding the vapor deposition mask 1 may be provided with a temperature controller controlling temperature of the vapor deposition mask 1, thereby suppressing an increase in temperature of the vapor deposition mask 1. In the case of this configuration, the vapor deposition mask 1 may be made from nickel, which has a higher coefficient of linear expansion than invar material but has good formability, or the like.

The size of the vapor deposition mask 1 (size in a plan view), that is, the size of the metal mask 10 (size in a plan view) may be determined appropriately for the size of the film target substrate 60 and the like, and is not particularly limited.

The thickness of the metal mask 10 may be determined appropriately for the size (size in a plan view), weight, and the like of the vapor deposition mask 1, and is not particularly limited. The thickness of the metal mask 10 can be determined, for example, to have the same thickness of a metal mask in a compound mask in the related art including the metal mask and a resin mask in a layered manner. The metal mask 10 desirably has the thinnest possible thickness, and by reducing the thickness of the metal mask 10, occurrence of a shadow can be suppressed. The shadow indicates a non-vapor-deposited portion having a film thickness thinner than a target vapor deposition film thickness. However, in a case where the metal mask 10 has an extremely thin thickness, the strength of the vapor deposition mask 1 decreases. Accordingly, the thickness of the metal mask 10 is preferably determined within a range in which a sufficient strength can be maintained. Note that, since the vapor deposition mask 1 is a compound mask in which the metal mask 10 and the resin mask 20 are integrated with each other, the possibility of rupture or deformation can be reduced even with a thin thickness in comparison to a metal vapor deposition mask. Accordingly, the metal mask 10 preferably has a thickness of, for example, approximately 5 μm to 100 μm.

### Resin Mask 20

The resin mask 20 is provided with the above-described alignment markers 23. The resin mask 20 is also provided with the resin mask openings 21 in plurality as penetrating holes (openings, second openings) for forming a vapor deposition film, that penetrate the resin mask 20 in the Z-axial direction, transmit the vapor deposition particles 71, and correspond to part of a pattern actually obtained by vapor deposition using the vapor deposition mask 1. The resin mask openings 21 that are located in the metal mask openings 11 in a plan view and are not covered with the metal mask 10, are used for forming the vapor deposition film 72 by using the vapor deposition mask 1.

When the vapor deposition mask 1 is used in, for example, manufacturing an organic EL display device, a pattern actually obtained by vapor deposition using the vapor deposition mask 1 is, for example, a pattern of an organic film (e.g., a light-emitting layer) of the organic EL display device, and the resin mask openings 21 are formed into a pattern corresponding to the pattern (width and interval in the X-axial direction) of the organic film of the organic EL display device in the X-axial direction. Through scan vapor deposition, a vapor deposition film 72 is formed into lines shaped such that the resin mask openings 21 extend in the Y-axial direction.

In the resin mask 20, at least one resin mask opening group 22 is formed that is a group of the resin mask openings 21 gathered. FIGS. 2A and 2B and FIG. 3 illustrate an example case in which a plurality of (for example, three) resin mask opening groups 22 are formed in the resin mask 20 in the X-axial direction.

In the resin mask 20, each of the resin mask opening groups 22 is provided in correspondence to one of the metal mask openings 11, and a plurality of resin mask openings 21 are provided in correspondence to each of the metal mask openings 11. Note that, in FIG. 1 to FIG. 4, the number of the resin mask openings 21 in the metal mask opening 11 is reduced for convenience of illustration.

Each of the resin mask opening groups 22 is disposed in a position overlapping with the corresponding metal mask opening 11 so that part of the resin mask openings 21 constituting the resin mask opening group 22 is located in the metal mask opening 11 and is exposed from the metal mask opening 11.

All the resin mask openings 21 according to the present embodiment have the same shape. As illustrated in FIG. 1 to FIG. 3, the resin mask openings 21 have, for example, a slot shape, and are arranged in a matrix shape in which the resin mask openings 21 are aligned in plurality in both the X-axial direction and the Y-axial direction.

As described above, the metal mask 10 includes the tapered metal remaining portions 12 disposed at both end portions of each of the metal mask openings 11 in the Y-axial direction and protruding toward the center of each of the metal mask openings 11 in the Y-axial direction so that the opening length of each of the metal mask openings 11 in the Y-axial direction increases from the center in the X-axial direction toward both end portions in the X-axial direction.

Thus, as illustrated in FIG. 1 and FIGS. 2A and 2B, some of the plurality of resin mask openings 21 located at both ends in the Y-axial direction (i.e., both ends in the Y-axial direction and their vicinities) in the resin mask opening group 22 are covered partially or entirely with the metal remaining portions 12.

Accordingly, in each of the resin mask opening groups 22, the number of the resin mask openings 21 (the number of openings) exposed from the metal mask opening 11 and aligned in the Y-axial direction, and the opening areas and opening shapes of the resin mask openings 21 partially covered with the metal remaining portions 12 (i.e., the shapes of portions not covered with the metal remaining portions 12, in other words, the shapes of portions that are exposed from the metal mask opening 11 of the resin mask openings 21) differ depending on the position in the X-axial direction.

The metal remaining portions 12 occupy a larger area in the Y-axial direction at the center of each of the resin mask opening groups 22 in the X-axial direction, so that the number (total opening length) of the resin mask openings 21 aligned in the Y-axial direction is substantially smaller, and the metal remaining portions 12 occupy a smaller area in the Y-axial direction as the position is away from the center of each of the resin mask opening groups 22 in the X-axial direction, so that the number (total opening length) of the resin mask openings 21 aligned in the Y-axial direction becomes substantially greater.

In this way, in each of the resin mask opening groups 22, the resin mask openings 21 exposed from the metal mask opening 11 and aligned in the Y-axial direction in the respective positions in the X-axial direction have such total opening lengths in the Y-axial direction as to increase from the center in the X-axial direction toward both end portions in the X-axial direction.

In scan vapor deposition, the film thickness T (Å) of the vapor deposition film 72 formed using the resin mask openings 21 located on a line passing through a desired position x of the vapor deposition mask 1 in the X-axial direction is represented by Equation (1) below:

T=D×R/S (1)

where S is a scan speed (mm/s) of the film target substrate 60 (or the vapor deposition unit 52), R is a vapor deposition rate (Å/s), and D is a total length (mm) in the Y-axial direction of portions, exposed from the metal mask opening 11 (in other words, portions not covered with the metal remaining portions 12 of the metal mask 10), of all the resin mask openings 21 located on the line passing through the position x and located on the same straight line in the Y-axial direction.

Note that the vapor deposition rate R is a speed of forming the vapor deposition film 72 on the film target substrate 60, that depends on the amount of the vapor deposition particles 71 emitted from the vapor deposition source openings 31 of the vapor deposition source 30 and the distance between the film target substrate 60 and the vapor deposition source 30.

From Equation (1) above, when the scan speed S and the vapor deposition rate R have certain fixed values, the film thickness T of the vapor deposition film 72 depends on the total length, indicated by D, in the Y-axial direction of portions, exposed from the metal mask opening 11, of the resin mask openings 21.

The number of the resin mask openings 21 aligned in the Y-axial direction in each of rows, the length of the resin mask openings 21 in the Y-axial direction, and the length in the Y-axial direction of the metal remaining portions 12 of the metal mask 10 in each of the positions in the X-axial direction (in other words, the length in the Y-axial direction of the resin mask openings 21 aligned in the Y-axial direction in each of the rows and covered with the metal remaining portions 12) can be determined appropriately for the film thickness of the vapor deposition film 72 formed on the film target substrate 60.

The resin mask 20 can be made from resin (plastic) material similar to the material of a resin mask used in a vapor deposition mask in the related art. The resin material is not particularly limited but is preferably a lightweight material with which high definition resin mask openings 21 can be formed by laser machining or the like and that has a low rate of change in size when heated or over time and low moisture absorbency.

Such resin materials include, for example, polyimide resin, polyamide resin, polyamide-imide resin, polyester resin, polyethylene resin, polyvinyl alcohol resin, polypropylene resin, polycarbonate resin, polystyrene resin, and polyacrylonitrile resin. Among these, for example, polyimide, which has a high glass transition temperature of 400° C. or higher, is rigid and strong, and has a high heat resistance, is suitable for the material of the resin mask 20.

The resin mask 20 is formed to have the same size (size in a plan view) as that of the metal mask 10, for example. However, the present embodiment is not limited to this configuration, and the resin mask 20 and the metal mask 10 may not necessarily have the same size as long as the resin mask 20 is formed, overlapping with the metal mask openings 11.

The thickness of the resin mask 20 is not particularly limited; however, the resin mask 20 desirably has the thinnest possible thickness to suppress occurrence of a shadow. However, in a case where the resin mask 20 has an extremely thin thickness, a defect such as a pinhole is likely to occur, and this also increases the possibility of deformation and the like. Accordingly, the resin mask 20 preferably has a thickness of, for example, approximately 5 μm to 25 μm.

### Manufacturing Method for the Vapor Deposition Mask 1

The metal mask 10 and the resin mask 20 are integrated with each other without using an adhesive or the like, and are provided in contact with each other. The resin mask 20 is formed by a resin film disposed on the metal mask 10 in a layered manner.

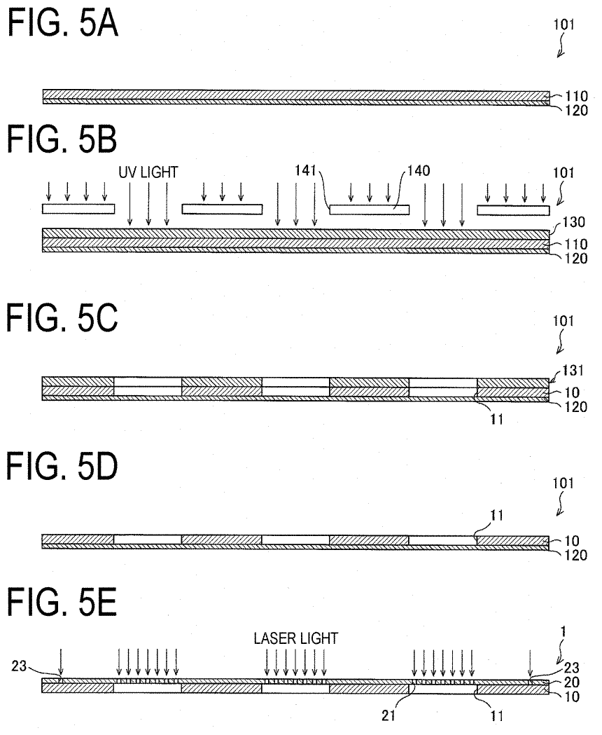

A manufacturing method for the vapor deposition mask 1 will be described below with reference to FIGS. 5A to 5E.

FIGS. 5A to 5E are cross-sectional views illustrating steps, in order, of an example of a manufacturing method for the vapor deposition mask 1.

First, as illustrated in FIG. 5A, resin such as polyimide is applied onto one of main surfaces of a metal mask base material 110 constituted by a metal plate and being a base material of the metal mask 10, thereby forming a resin film (forming a resin film in an integrated manner) as a base material of the resin mask 20 on the one main surface of the metal mask base material 110. With this step, a compound mask base material 101 is prepared in which a resin mask base material 120 constituted by the resin film is disposed on the one main surface of the metal mask base material 110. Note that a method of preparing the compound mask base material 101 is not particularly limited, and, for example, a commercially available metal plate with a resin film may be purchased as the compound mask base material 101, or the compound mask base material 101 may be prepared by, for example, applying resin on a surface of a metal plate to provide a resin film as described above.

Next, the metal mask openings 11 penetrating only the metal mask base material 110 are formed in the metal mask base material 110 of the compound mask base material 101 to form the metal mask 10.

Note that a method of forming the metal mask openings 11 in the metal mask base material 110 is not particularly limited as long as the metal mask openings 11 are formed only in the metal mask base material 110.

For example, as illustrated in FIG. 5B, a photoresist 130 is applied onto a surface, not provided with the resin mask base material 120, of the metal mask base material 110, and is exposed to light and developed through a photomask 140 in which openings 141 are formed. With this step, as illustrated in FIG. 5C, a resist pattern 131 constituted by the photoresist 130 is formed on the surface of the metal mask base material 110. Then, only the metal mask base material 110 is etched with the resist pattern 131 used as an etching mask, thereby forming the metal mask openings 11 in the metal mask base material 110. In this way, the metal mask 10 is formed.

The metal mask base material 110 can be etched by, for example, wet etching. An etching solution used in wet etching is not particularly limited, and a known etching solution may be selected appropriately.

Note that FIGS. 5B and 5C illustrate an example case in which a positive-working photoresist, with which an exposed portion dissolves in a developing solution, is used as the photoresist 130. However, the present embodiment is not limited to this case, and obviously, a negative-working photoresist, with which an exposed portion does not dissolve in a developing solution, may be used as the photoresist 130.

Next, as illustrated in FIG. 5D, the resist pattern 131 is stripped off using a resist stripper.

Thereafter, as illustrated in FIG. 5E, laser light is radiated, for example, from the resin mask base material 120 side (i.e., the resin film side), so that the resin mask openings 21 and the alignment markers 23 penetrating only the resin mask base material 120 are formed in the resin mask base material 120, thereby forming the resin mask 20.

Note that a known laser light radiation device, for example, a solid laser such as a YAG laser, or a gas laser such as an excimer laser, can be used as a laser light radiation device radiating the laser light.

These steps can provide the compound vapor deposition mask 1 in which the metal mask 10 constituted by the metal mask base material 110 formed to have the metal mask openings 11 and the resin mask 20 constituted by the resin mask base material 120 formed to have the resin mask openings 21 are integrated with each other.

Note that the description with reference to FIGS. 5A to 5E has exemplified the case in which the metal mask base material 110 is etched to form the metal mask openings 11 in the metal mask base material 110 first, and then the resin mask openings 21 are formed in the resin mask base material 120. However, the present embodiment is not limited to this case, and the resin mask openings 21 may be formed in the resin mask base material 120 first, and then the metal mask base material 110 may be etched to form the metal mask openings 11 in the metal mask base material 110.

The description with reference to FIG. 5E has exemplified the case in which laser light is radiated to the compound mask base material 101 from the resin mask base material 120 side to form the resin mask openings 21 in the resin mask base material 120. However, the present embodiment is not limited to this case, and laser light may be radiated to the compound mask base material 101 from the metal mask 10 side (i.e., the metal mask base material 110 side).

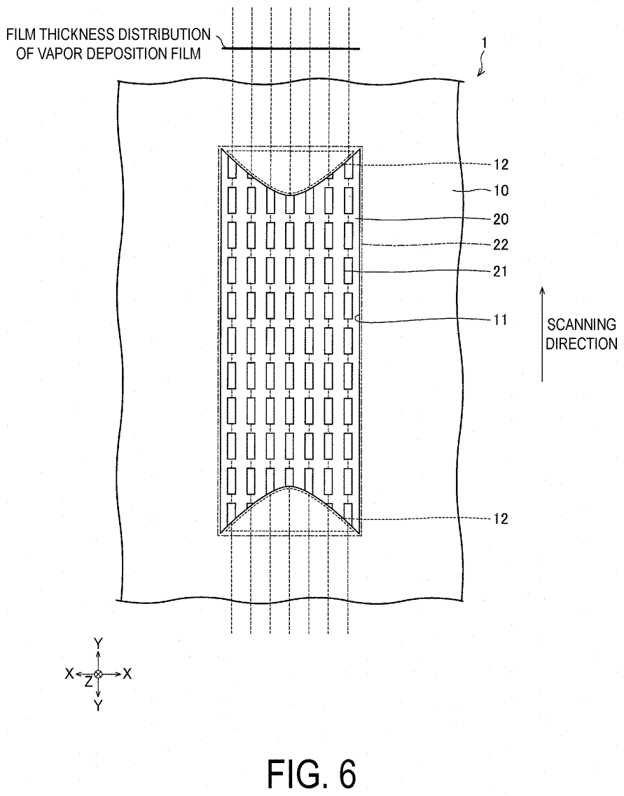

FIG. 6 is a bottom view illustrating a schematic configuration of main portions of a vapor deposition mask 1, when viewed from the metal mask 10 side, obtained by radiating laser light to the compound mask base material 101 from the metal mask 10 side, together with the film thickness distribution of a vapor deposition film 72 formed using the vapor deposition mask 1.

When laser light is radiated from the resin mask base material 120 side to form the resin mask openings 21, the resin mask openings 21 having the same shape are formed even outside the metal mask openings 11 as illustrated in FIG. 1 to FIG. 3. However, some of these resin mask openings 21 are partially covered with the metal remaining portions 12, so that the resin mask openings 21 partially covered with the metal remaining portions 12 and exposed from the metal mask openings 11 (in other words, the resin mask openings 21 exposed from the metal mask openings 11 at the end portions of the metal mask openings 11 in the Y-axial direction) have different opening shapes depend portioning on the position in the X-axial direction. This configuration changes the total opening lengths in the Y-axial direction of the resin mask openings 21 exposed from the metal mask openings 11 and aligned in the Y-axial direction, depending on the position in the X-axial direction.

On the other hand, when laser light is radiated from the metal mask 10 side to form the resin mask openings 21, the laser light radiated onto the metal mask 10 does not pass through the metal mask 10, and as illustrated in FIG. 6, the resin mask openings 21 are formed only in the metal mask opening 11. This configuration changes the opening shapes of the resin mask openings 21 exposed from the metal mask opening 11 at the end portions of the metal mask opening 11 in the Y-axial direction, depend portioning on the position in the X-axial direction. Thus, even in this case, the total opening lengths in the Y-axial direction of the resin mask openings 21 exposed from the metal mask opening 11 and aligned in the Y-axial direction are changed depending on the position in the X-axial direction.

Accordingly, in either of the above-described cases, the total opening lengths in the Y-axial direction of the resin mask openings 21 exposed from the metal mask opening 11 and aligned in the Y-axial direction in the respective positions in the X-axial direction can increase from the center in the X-axial direction toward both end portions in the X-axial direction.

However, direct radiation of laser light onto the metal mask 10 may cause a failure due to interference with the laser light. Thus, as illustrated in FIG. 5E, laser light is desirably radiated from the resin mask base material 120 side to form the resin mask openings 21.

Furthermore, according to the present embodiment, the metal mask base material 110 and the resin mask base material 120 are integrated with each other, and the metal mask openings 11 and the resin mask openings 21 are formed as described above. Thus, no alignment marker is required for positioning between the metal mask 10 and the resin mask 20.

Note that, as described above, the alignment markers 23 for positioning between the film target substrate 60 and the vapor deposition mask 1 are formed in the resin mask 20 with laser light.

In this way, the vapor deposition mask 1 is provided with no alignment marker for positioning between the metal mask 10 and the resin mask 20, so that the resin mask 20 includes no alignment marker for the metal mask 10 and includes only the alignment markers 23 for the film target substrate 60 as alignment markers.

### Advantageous Effects

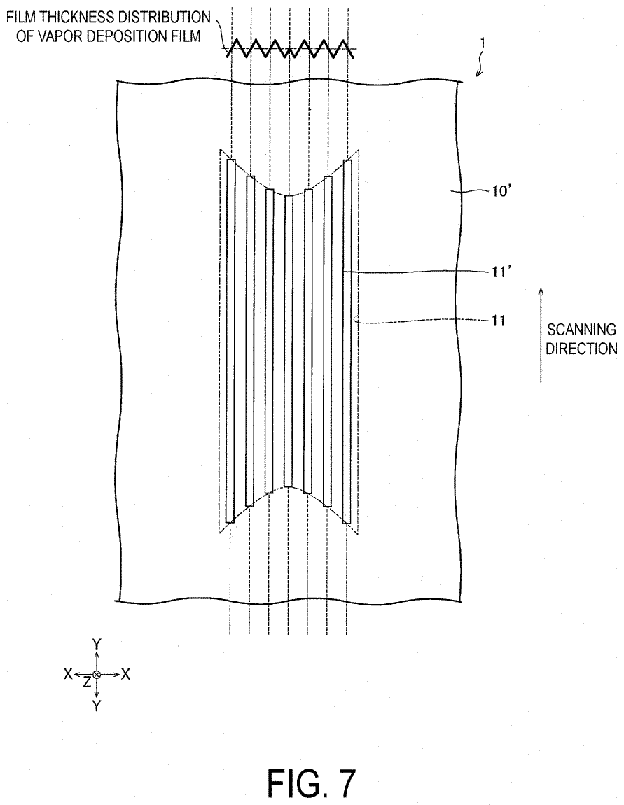

FIG. 7 is a bottom view illustrating a schematic configuration of main portions of a vapor deposition mask for comparison including a metal mask 10′, together with the film thickness distribution of a vapor deposition film formed using the vapor deposition mask for comparison.

As illustrated in FIG. 7, the vapor deposition mask for comparison includes a plurality of slit-like (belt-like) metal mask openings 11′ as openings in a region corresponding to the vapor deposition block 51 of the present embodiment, instead of the one metal mask opening 11 and the plurality of resin mask openings 21 illustrated in FIG. 1. Other than this point, the vapor deposition mask for comparison has the same configuration as that of the vapor deposition mask 1 illustrated in FIG. 1 to FIG. 4, and a vapor deposition apparatus including the vapor deposition mask for comparison has the same configuration as that of the vapor deposition apparatus 50 illustrated in FIG. 4.

Note that, in FIG. 7, the number of the metal mask openings 11′ is reduced for convenience of illustration. In the example illustrated in FIG. 7, similar to the example illustrated in FIG. 2B, the vapor deposition source opening 31 is located in the center of each of the limiting plate openings 42 and in the center of the metal mask opening 11′ in the X-axial direction and the Y-axial direction in the region corresponding to the vapor deposition block 51 in a plan view.

When the skit-like metal mask openings 11′ illustrated in FIG. 7 are provided instead of the openings, illustrated in FIG. 1, corresponding to the group of the slot-like resin mask openings 21 partially covered with the metal remaining portion 12, the metal mask openings 11′ and the metal mask opening 11 actually have different lengths in the Y-axial direction in the respective centers in the X-axial direction from Equation (1) and Equation (2) (described later), in order to form vapor deposition films 72 having the same film thickness. For example, the length of the metal mask openings 11′ needs to be shortened by a total length in the Y-axial direction of non-openings between adjacent slot-like resin mask openings 21. However, for convenience of description and illustration, the following description is provided assuming that the length of each of the metal mask openings 11′ in the Y-axial direction in the center in the X-axial direction is equal to the length of the metal mask opening 11 in the Y-axial direction in the center in the X-axial direction, whereby Equation (1) is equal to Equation (2).

The metal mask openings 11′ are formed to be longer in the Y-axial direction than in the X-axial direction and to have such opening lengths in the Y-axial direction as to increase continuously from the center in the X-axial direction toward both end portions in the X-axial direction in a symmetrical manner with respect to the center in the X-axial direction.

The film thickness (Å) T′ of the vapor deposition film 72 formed using the metal mask opening 11′ located on a line passing through a desired position x of the vapor deposition mask 1 in the X-axial direction is represented by Equation (2) below:

T′=D′×R/S (2)

where S is a scan speed (mm/s) of the film target substrate 60 (or the vapor deposition unit 52), R is a vapor deposition rate (Å/s), and D′ is a length (mm) in the Y-axial direction of the metal mask opening 11′ located on the line passing through the position x.

From Equation (2) above, when the scan speed S and the vapor deposition rate R have certain fixed values, the film thickness T′ of the vapor deposition film 72 depends on the length, indicated by D′, in the Y-axial direction of the metal mask opening 11′.

Thus, as illustrated in FIG. 7, by forming the metal mask openings 11′ aligned in the X-axial direction to have such opening lengths in the Y-axial direction as to increase from the center in the X-axial direction toward both end portions in the X-axial direction in the region corresponding to the vapor deposition block 51 of the present embodiment, the film thickness distribution of the vapor deposition film 72 can be improved.

However, with the existing metal processing technology, it may be difficult to accurately form openings (in this case, the metal mask openings 11′) in a metal plate to be the metal mask base material. Also, when the metal mask 10′ illustrated in FIG. 7 is used as a vapor deposition mask, it may be difficult to form a high definition vapor deposition film pattern due to the effect of positional offset, warping, and the like, resulting from thermal expansion of the metal plate.

In the metal mask 10′ illustrated in FIG. 7, the opening length in the Y-axial direction is determined for each of the metal mask openings 11′ (i.e., in metal mask opening units). When the metal mask openings 11′ are formed into slits continuous in the Y-axial direction and have different opening lengths in the Y-axial direction in this way, the film thickness distribution is corrected in units of the widths of the metal mask openings 11′ in the X-axial direction, with reference to FIG. 7 illustrating the film thickness distribution of the vapor deposition film 72.

However, the amount of the vapor deposition particles 71 emitted from the vapor deposition source opening 31 does not vary stepwise in units of the widths of the metal mask openings 11′ in the X-axial direction but varies continuously as illustrated as the shapes of the end portions in the Y-axial direction of the metal mask opening 11 of the vapor deposition mask 1 of the present embodiment.

Thus, when, for example, the film thickness distribution is corrected in the central position of each of the metal mask openings 11′ in the X-axial direction, the metal mask opening 11′ located in the center of each of the vapor deposition blocks 51 (i.e., the metal mask opening 11′ located in the center in the X-axial direction in the group of the metal mask openings 11′) has an opening length in the Y-axial direction at both end portions of the metal mask opening 11′ in the X-axial direction shorter than the opening length in the Y-axial direction of the metal mask opening 11 in the same position, with reference to FIG. 7 illustrating the metal mask opening 11 of the vapor deposition mask 1 with the chain double-dashed line.

In the example illustrated in FIG. 7, in the metal mask opening 11′ located in the center of each of the vapor deposition blocks 51, both end portions in the Y-axial direction in the central position in the X-axial direction of the metal mask opening 11′ are located on the contour of the metal mask opening 11; however, for example, both end portions in the Y-axial direction at both end portions in the X-axial direction of the metal mask opening 11′ are located inside the contour of the metal mask opening 11.

Furthermore, each of the metal mask openings 11′ other than the metal mask opening 11′ located in the center of each of the vapor deposition blocks 51 has an opening length in the Y-axial direction longer than that of the metal mask opening 11 at one end portion in the X-axial direction (the end portion on the side closer to the center of the vapor deposition block 51), but has an opening length in the Y-axial direction shorter than that of the metal mask opening 11 at the other end portion (the end portion on the side opposite to the side closer to the center of the vapor deposition block 51).

In a case where a description is given with the example illustrated in FIG. 7, in each of the metal mask openings 11′ other than the metal mask opening 11′ located in the center of each of the vapor deposition blocks 51, both end portions in the Y-axial direction in the central position in the X-axial direction of the metal mask opening 11′ are located on the contour of the metal mask opening 11; however, for example, both end portions in the Y-axial direction at the above-described one end portion of the metal mask opening 11′ are located outside the contour of the metal mask opening 11, and both end portions in the Y-axial direction at the above-described other end portion of the metal mask opening 11′ are located inside the contour of the metal mask opening 11.

As a result, when the metal mask 10′ illustrated in FIG. 7 is used as a vapor deposition mask, the film thickness distribution is generated stepwise in the X-axial direction microscopically as illustrated in FIG. 7.

Note that the same as in the example illustrated in FIG. 7 can be applied to a case in which metal mask openings 11′ are formed into slots intermittent in the Y-axial direction and the number of the metal mask openings 11′ aligned in the Y-axial direction is changed depending on the position in the X-axial direction.

In this way, when the opening lengths in the Y-axial direction of the openings of the vapor deposition mask are changed in units of the openings of the vapor deposition mask, the film thickness distribution can be corrected only in units of the openings of the vapor deposition mask. Thus, the opening lengths cannot be adjusted minutely, and the film thickness distribution of the vapor deposition film cannot be corrected minutely.

The openings (resin mask openings) of the resin mask are minute and are typically formed all together, not individually. Thus, more highly accurate openings can be formed in the resin mask than in the metal mask, and the vapor deposition mask including the resin mask can be reduced in weight. However, the film thickness distribution of a formed vapor deposition film cannot be corrected with the resin mask.

Basically, the film thickness distribution of a formed vapor deposition film 72 varies continuously. Thus, it is ideal to continuously vary the total opening length of the vapor deposition mask in the Y-axial direction.

According to the present embodiment, as illustrated in FIG. 1 to FIG. 3, each of the metal masks 10 is provided with the metal remaining portions 12 that continuously vary the opening length of the metal mask opening 11 in the Y-axial direction in such a manner that the opening length of the metal mask opening 11 in the Y-axial direction increases from the center in the X-axial direction toward both end portions in the X-axial direction in the corresponding vapor deposition block 51. Thus, according to the present embodiment, the opening lengths in the Y-axial direction of the resin mask openings 21 exposed from the metal mask opening 11 and not covered with the metal mask 10 can be varied continuously so as to increase from the center of the resin mask opening group 22 in the X-axial direction toward both end portions in the X-axial direction.

In this way, according to the present embodiment, a vapor deposition film 72 is formed through the resin mask openings 21 of the resin mask 20 on which a vapor deposition film pattern having higher definition than on the metal mask 10′ can be formed. Furthermore, according to the present embodiment, the opening lengths can be varied using the resin mask openings 21, instead of correcting the opening lengths in units of the openings in the case of varying the opening lengths in the Y-axial direction of the metal mask openings 11′ arranged in the X-axial direction as described above. Thus, according to the present embodiment, the total opening lengths in the Y-axial direction of the resin mask openings 21 in the rows aligned in the X-axial direction (i.e., the total opening lengths in the Y-axial direction of the resin mask openings 21 actually penetrating the vapor deposition mask 1, exposed from the metal mask opening 11, and aligned in the Y-axial direction) can be varied continuously as described above, so that the film thickness distribution of a formed vapor deposition film 72 can be corrected minutely, and that the accuracy in correcting the film thickness distribution can be enhanced. Thus, according to the present embodiment, a vapor deposition film 72 having high definition and uniform film thickness can be formed. Accordingly, an excellent organic EL display device with no inappropriate light emission such as uneven light emission in a streaked manner can be manufactured.

Furthermore, in the present embodiment, some of the resin mask openings 21 are covered with the metal mask 10 (in specific, the metal remaining portions 12) to vary the opening lengths of the resin mask openings 21 as described above, so that all the resin mask openings 21 can be formed into the same shape, and that no special laser opening processing or the like for varying the opening lengths of the resin mask openings 21 is required. Accordingly, with the compound mask (FHM) including the metal mask 10 and the resin mask 20 in a layered manner, the film thickness distribution of the vapor deposition film 72 can be corrected readily.

### Modified Example 1

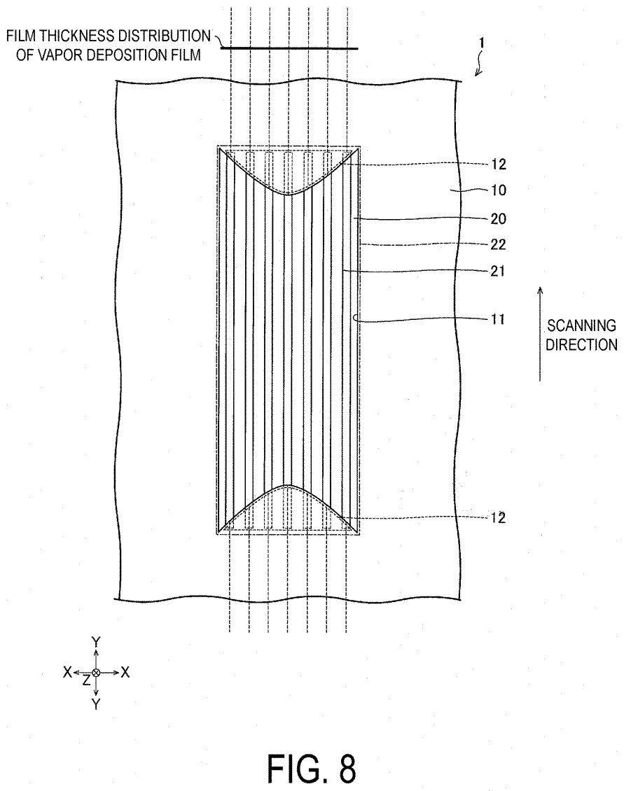

FIG. 8 is a bottom view illustrating a schematic configuration of main portions of a vapor deposition mask 1, when viewed from a metal mask 10 side, according to this modified example, together with the film thickness distribution of a vapor deposition film formed using the vapor deposition mask 1.

The description with reference to FIG. 1 to FIG. 3 has exemplified the case in which the resin mask openings 21 having a slot shape are arranged in the resin mask 20 in a matrix shape in which the resin mask openings 21 are aligned in plurality in both the X-axial direction and the Y-axial direction, in each of the vapor deposition blocks 51.

However, as described above, from Equation (1) above, when the scan speed S and the vapor deposition rate R have certain fixed values, the film thickness T of the vapor deposition film 72 depends on the total length, indicated by D, in the Y-axial direction of portions, exposed from the metal mask opening 11, of the resin mask openings 21.

Thus, as illustrated in FIG. 8, a resin mask opening group 22 may include resin mask openings 21 having the same opening width in the X-axial direction and different lengths in the Y-axial direction as rows of resin mask openings 21 extending in the Y-axial direction.

In this modified example, instead of the plurality of slot-like resin mask openings 21 arranged in a matrix shape in the X-axial direction and the Y-axial direction as illustrated in FIG. 1, the plurality of slit-like (belt-like) resin mask openings 21 aligned in the X-axial direction are provided as openings in a region corresponding to the vapor deposition block 51, and all the resin mask openings 21 are partially covered with the metal remaining portions 12, as illustrated in FIG. 8. Other than this point, the vapor deposition mask 1 according to this modified example has the same configuration as that of the vapor deposition mask 1 illustrated in FIG. 1 to FIG. 4. Note that, also in FIG. 8, the number of the resin mask openings 21 is reduced for convenience of illustration.

Also in this modified example, as illustrated in FIG. 8, the resin mask openings 21 can be partially covered with the metal mask 10 (in specific, the metal remaining portions 12) to continuously vary the opening lengths in the Y-axial direction of the resin mask openings 21 exposed from the metal mask opening 11 and not covered with the metal mask 10 in such a manner as to increase from the center of the resin mask opening group 22 in the X-axial direction toward both end portions in the X-axial direction.

In this way, in the present embodiment, the shape of the resin mask openings 21 is not particularly limited. However, since the resin mask openings 21 have a slot-like shape and are provided in plurality in the Y-axial direction, non-openings being bridges (crosspieces) extending in the X-axial direction exist between the resin mask openings 21 aligned in the Y-axial direction. Thus, the vapor deposition mask 1 can have enhanced strength in the case of the slot-like resin mask openings 21 in comparison to the case of the slit-like resin mask openings 21.

### Modified Example 2

The description with reference to FIG. 1 to FIG. 3 has exemplified the case in which the metal remaining portions 12 are disposed at both end portions of the metal mask opening 11 in the Y-axial direction and are formed to have such a length in the Y-axial direction as to decrease from the center in the X-axial direction toward both end portions in the X-axial direction.

However, the metal mask 10 is only required to be provided with a metal remaining portion 12 partially covering at least some of the plurality of resin mask openings 21 so that the opening length of the metal mask opening 11 in the Y-axial direction increases from the center in the X-axial direction toward both end portions in the X-axial direction, that the metal mask opening 11 partially exposes the plurality of resin mask openings 21, and that the resin mask openings 21 exposed from the metal mask opening 11 and aligned in the Y-axial direction in the respective positions in the X-axial direction have such total opening lengths in the Y-axial direction as to increase from the center in the X-axial direction toward both end portions in the X-axial direction.

Thus, the metal remaining portion 12 is not necessarily required to be provided at each of both end portions in the Y-axial direction as long as the metal remaining portion 12 is formed to have such a length in the Y-axial direction as to decrease from the center in the X-axial direction toward both end portions in the X-axial direction.

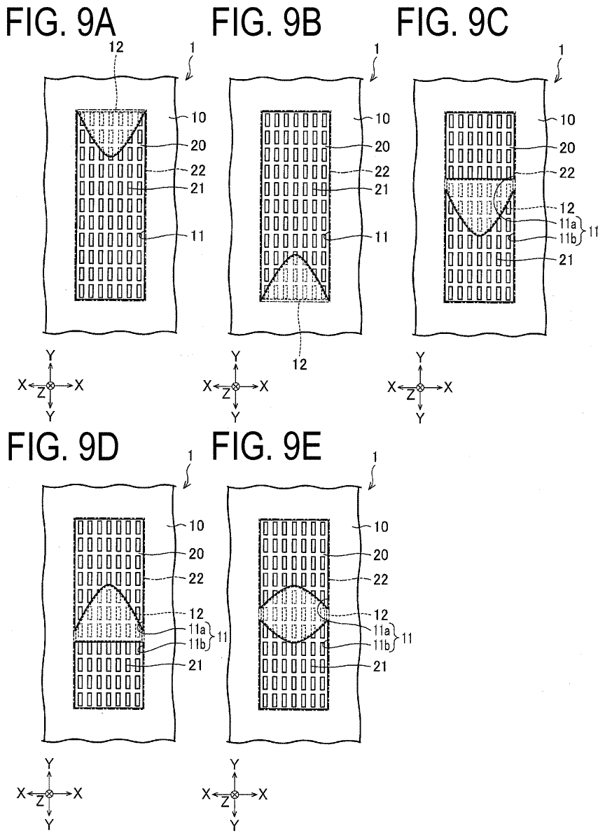

FIGS. 9A to 9E are bottom views each illustrating an example of a schematic configuration of main portions of a vapor deposition mask 1, when viewed from a metal mask 10 side, according to this modified example.

The metal remaining portion 12 may be provided, for example, at at least one of end portions of the metal mask opening 11 in the Y-axial direction, at each of both end portions of the metal mask opening 11 in the Y-axial direction as illustrated in FIG. 1 to FIG. 3 and FIG. 8, or at one of the end portions of the metal mask opening 11 in the Y-axial direction as illustrated in FIGS. 9A and 9B.

Alternatively, as illustrated in FIGS. 9C to 9E, the metal remaining portion 12 may be provided across the metal mask opening 11 in the X-axial direction so as to divide the metal mask opening 11 into a plurality of sections (e.g., two divided metal mask openings 11a and 11b). In other words, the metal remaining portion 12 may be provided across the resin mask opening group 22 in the X-axial direction so as to divide the resin mask opening group 22 into a plurality of groups.

In this case, the metal remaining portion 12 may be formed to have a shape of, for example, a planoconvex lens illustrated in FIGS. 9C and 9D or a biconvex lens illustrated in FIG. 9E, between both end portions of the metal mask opening 11 in the Y-axial direction (in other words, between both end portions of the resin mask opening group 22 in the Y-axial direction, for example, in the center in the Y-axial direction).

Note that, when the metal remaining portion 12 is provided across the metal mask opening 11 in the X-axial direction in this way, the metal mask opening 11 may have the same outside shape (i.e., a rectangular shape) as that of the resin mask opening group 22 as illustrated in FIGS. 9C to 9E.

When the metal remaining portion 12 has a shape protruding in one direction as illustrated in FIGS. 9A to 9D, the metal remaining portion 12 may be formed protruding upstream in the scanning direction of the film target substrate 60 or downstream in the scanning direction of the film target substrate 60.

FIGS. 9A to 9E exemplify cases in which, by radiating laser light to the compound mask base material 101 from the resin mask base material 120 side, some of the plurality of resin mask openings 21 are partially covered with the metal remaining portion 12 as illustrated with the broken lines in FIGS. 9A to 9E. However, this modified example is not limited to these cases, and may have a configuration in which, by radiating laser light to the compound mask base material 101 from the metal mask 10 side, the resin mask openings 21 are formed only in the metal mask opening 11.

FIGS. 9A to 9E exemplify cases in which the resin mask openings 21 are arranged in a matrix shape. However, this modified example is not limited to these cases. As illustrated in FIG. 8, the resin mask openings 21 may be arranged more than one only in the X-axial direction and only one in the Y-axial direction. Alternatively, each of the resin mask openings 21 arranged in the X-axial direction may have a shape extending in the Y-axial direction, for example, a slit shape. Thus, also in this modified example, all the resin mask openings 21 may be partially covered with the metal remaining portion 12.

### Modified Example 3

The present embodiment has been described, exemplifying the case in which the metal mask 10 includes at least one metal mask opening 11 (three in the example illustrated in FIG. 1 to FIG. 3) as an opening (first opening), and the resin mask 20 includes at least one resin mask opening group 22 (second opening group) (three in the example illustrated in FIG. 1 to FIG. 3) overlapping with the metal mask opening 11 and including the plurality of resin mask openings 21.

However, the present embodiment is not limited thereto. Although not illustrated, the resin mask openings 21 may be provided with uniform intervals over the entire resin mask 20.

Also in this case, the metal mask 10 is provided between the resin mask 20 and the vapor deposition source 30, so that the vapor deposition film 72 is formed by the vapor deposition particles 71 passing through the resin mask openings 21 exposed from the metal mask opening 11 in the same way. Thus, this case can also yield advantageous effects similar to the above-described advantageous effects of the present embodiment.

### Second Embodiment

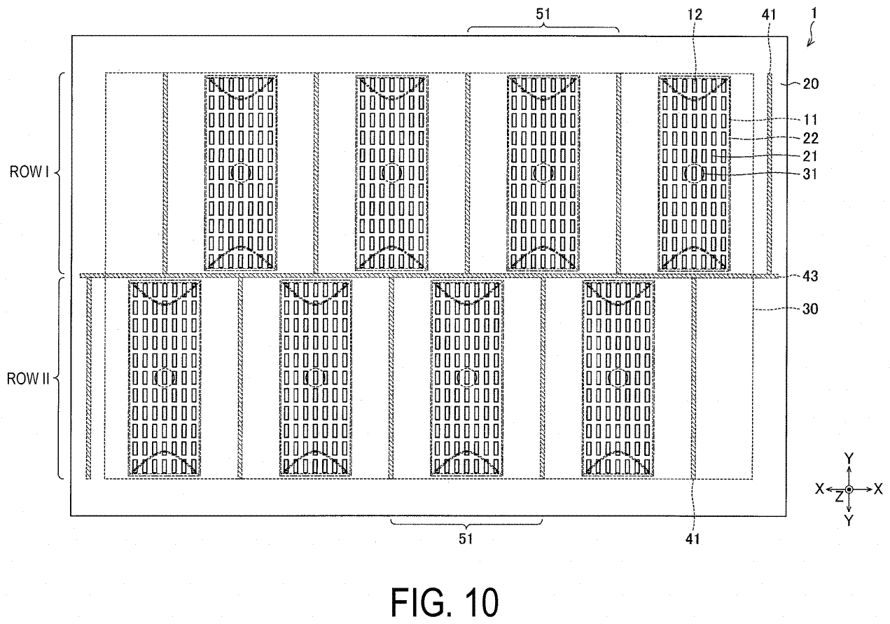

Another embodiment of the disclosure will be described below with reference to FIG. 10. The present embodiment will be stated by the differences between the present embodiment and the first embodiment, and components having the same functions as the components used in the first embodiment are appended with the same reference signs, and the description thereof is omitted.

FIG. 10 is a top view illustrating a schematic configuration of a vapor deposition mask 1, when viewed from a resin mask 20 side along the Z-axis, according to the present embodiment, together with other constituent elements of a vapor deposition apparatus 50 according to the present embodiment. In other words, FIG. 10 is a top view illustrating an example of a schematic configuration of main portions of the vapor deposition apparatus 50 according to the present embodiment. Note that FIG. 10 is illustrated as a see-through view enabling recognition of relative position relationship among the vapor deposition source openings 31 and the limiting plates 41, the metal mask openings 11 provided to the metal mask 10, and the resin mask opening groups 22 provided to the resin mask 20. Also in FIG. 10, the numbers of the metal mask openings 11 and the resin mask openings 21 are reduced for convenience of illustration.

The vapor deposition blocks 51 are aligned on a straight line in the X-axial direction in the first embodiment; however, the disclosure is not limited to this configuration. As illustrated in FIG. 10, the vapor deposition blocks 51 may be arranged, for example, in a zig-zag shape. Thus, in the vapor deposition mask 1 according to the present embodiment, the metal mask openings 11 and the resin mask opening groups 22 may be arranged, for example, in a zig-zag shape as illustrated in FIG. 10.

The vapor deposition apparatus 50 according to the present embodiment differs from the vapor deposition apparatus 50 according to the first embodiment in that, in the vapor deposition mask 1, the metal mask openings 11 and the resin mask opening groups 22 are arranged, for example, in two rows in a zig-zag shape, and the vapor deposition source openings 31 provided to the vapor deposition source 30 are arranged in two rows in a zig-zag shape, as illustrated in FIG. 10.

In the present embodiment, a plurality of the vapor deposition source openings 31 are arranged with uniform intervals in the X-axial direction in a row I located upstream in the scanning direction (movement direction) of the film target substrate 60 with respect to the vapor deposition unit 52, and a plurality of the vapor deposition source openings 31 are arranged with uniform intervals in a direction parallel to the X-axis in a row II located downstream in the scanning direction (movement direction) of the film target substrate 60 with respect to the vapor deposition unit 52. In the row I and the row II, the vapor deposition source openings 31 have the same intervals in the X-axial direction. However, the vapor deposition source openings 31 in the row I and the vapor deposition source openings 31 in the row II are arranged alternately in the X-axial direction.

Similar to the first embodiment, in the present embodiment, a plurality of the limiting plates 41 are arranged, as first limiting plates, in the X-axial direction in different positions in the X-axial direction while interposing the vapor deposition source openings 31 therebetween in the X-axial direction in each of the row I and the row II.

In the present embodiment, a scanning direction limiting plate 43 partitioning the vapor deposition blocks 51 in the scanning direction is disposed between the limiting plates 41 in the row I and the limiting plates 41 in the row II, as a second limiting plate extending in the X-axial direction. The edges of the limiting plates 41 in the row I on the side closer to the limiting plates 41 in the row II and edges of the limiting plates 41 in the row II on the side closer to the limiting plates 41 in the row I are connected with the scanning direction limiting plate 43.

Similar to the first embodiment, in the vapor deposition mask 1, the plurality of metal mask openings 11 and resin mask opening groups 22 are formed in correspondence to the vapor deposition source openings 31. Similar to the vapor deposition source openings 31, these metal mask openings 11 and resin mask opening groups 22 are also arranged along the two rows, the row I and the row II, parallel to the X-axis. The metal mask openings 11 and the resin mask opening groups 22 are arranged in the two rows in a zig-zag shape, and the metal mask openings 11 and the resin mask opening groups 22 in the row I are located in positions in the X-axial direction different from those in the row II. In other words, the metal mask openings 11 and the resin mask openings 21 in the row I and the metal mask openings 11 and the resin mask openings 21 in the row II are not located on the same straight lines in the Y-axial direction but are formed having positional offset in the X-axial direction.

Similar to the first embodiment, in the present embodiment, a pair of limiting plates 41 adjacent to each other in the X-axial direction, one vapor deposition source opening 31 located between the pair of limiting plates 41, one metal mask opening 11 located between the pair of limiting plates 41, and the resin mask opening group 22 constituted by the plurality of resin mask openings 21 arranged while being partially exposed from the metal mask opening 11 constitute one vapor deposition block 51.

The metal mask opening 11 and the resin mask openings 21 in each of the vapor deposition blocks 51 have the same relationship as that in the first embodiment. The vapor deposition mask 1 and the vapor deposition unit 52 according to the present embodiment have the same configurations as those of the vapor deposition mask 1 and the vapor deposition unit 52 according to the first embodiment, except that the vapor deposition blocks 51 are arranged in the two rows in a zig-zag shape and that the vapor deposition blocks 51 in the row I and the vapor deposition blocks 51 in the row II are partitioned by the scanning direction limiting plate 43.

Note that, similar to the first embodiment, in the present embodiment, each of the vapor deposition source openings 31 is desirably located, for example, in the center of the corresponding limiting plate opening 42 and in the center of the corresponding metal mask opening 11 in at least the X-axial direction (desirably, in the X-axial direction and the Y-axial direction as illustrated in FIG. 10) in a plan view.

FIG. 10 illustrates an example case in which, on a single vapor deposition source 30, the vapor deposition source openings 31 are arranged in a zig-zag shape while being located in the centers of the respective limiting plate openings 42 and in the centers of the respective metal mask openings 11 in the X-axial direction and the Y-axial direction. However, the present embodiment is not limited thereto. For example, a plurality of (for example, two) linear vapor deposition sources 30 on which a plurality of vapor deposition source openings 31 are arranged on a straight line in the X-axial direction may be arranged in the Y-axial direction in such a manner that the vapor deposition source openings 31 are located in the centers of the respective limiting plate openings 42 and in the centers of the respective metal mask openings 11 in the X-axial direction and the Y-axial direction.

### Advantageous Effects

Accordingly, the present embodiment can yield advantageous effects similar to those of the first embodiment.

Furthermore, in the present embodiment, the metal mask openings 11 and the resin mask opening groups 22 overlapping each other in the Z-axial direction are arranged in the two rows in a zig-zag shape as described above. Thus, according to the present embodiment, the distance in the X-axial direction between the metal mask opening 11 and the resin mask opening group 22 overlapping each other in the Z-axial direction and located in the row I and the metal mask opening 11 and the resin mask opening group 22 overlapping each other in the Z-axial direction, located in the row II, and adjacent to the former metal mask opening 11 and resin mask opening group 22 can be made shorter than the distance in the X-axial direction between the metal mask opening 11 and the resin mask opening group 22 overlapping each other in the Z-axial direction and located in the row I and the metal mask opening 11 and the resin mask opening group 22 overlapping each other in the Z-axial direction, located in the row I, and adjacent to the former metal mask opening 11 and resin mask opening group 22.

Thus, according to the present embodiment, for example, without changing intervals in the X-axial direction of the vapor deposition blocks 51 aligned in the X-axial direction, or even when the intervals are greater than those in the first embodiment, the number of the metal mask openings 11 and the resin mask opening groups 22 arranged in different positions in the X-axial direction can be increased.

Accordingly, by adjusting the distance in the X-axial direction between the metal mask opening 11 and the resin mask opening group 22 overlapping each other in the Z-axial direction and located in the row I and the metal mask opening 11 and the resin mask opening group 22 overlapping each other in the Z-axial direction, located in the row II, and adjacent to the former metal mask opening 11 and resin mask opening group 22, a large organic EL display device can be manufactured, or a large number of organic EL display devices can be manufactured together.

Although the description is omitted, obviously, the same modifications as those of the first embodiment may be applied to the present embodiment.

### Supplement

According to aspect 1 of the disclosure, a vapor deposition mask 1 includes: a metal mask 10; and a resin mask 20, the metal mask 10 and the resin mask 20 being layered. The metal mask 10 includes at least one first opening (metal mask opening 11). The at least one first opening has an opening length in a first direction (Y-axial direction), the opening length increasing from a center in a second direction (X-axial direction) toward both end portions in the second direction, the second direction being orthogonal to the first direction. The resin mask 20 includes a plurality of second openings (resin mask openings 21). The plurality of second openings are arranged at least one in the first direction and more than one in the second direction. The second openings exposed from the at least one first opening and aligned in the first direction in respective positions in the second direction have total opening lengths in the first direction, the total opening lengths increasing from the center in the second direction toward both end portions in the second direction.

According to aspect 2 of the disclosure, in the vapor deposition mask 1 having the configuration of aspect 1, the metal mask 10 may include at least one metal remaining portion 12 having a length in the first direction, the length decreasing from the center in the second direction toward both end portions in the second direction.

According to aspect 3 of the disclosure, in the vapor deposition mask 1 having the configuration of aspect 2, the at least one metal remaining portion 12 may be disposed at at least one of end portions of the at least one first opening in the first direction.

According to aspect 4 of the disclosure, in the vapor deposition mask 1 having the configuration of aspect 2 or 3, the at least one metal remaining portion 12 may include a plurality of metal remaining portions 12, and the plurality of metal remaining portions 12 may be disposed at both end portions of the at least one first opening in the first direction.

According to aspect 5 of the disclosure, in the vapor deposition mask 1 having the configuration of aspect 2 or 3, the at least one metal remaining portion 12 may be disposed at only one of end portions of the at least one first opening in the first direction.

According to aspect 6 of the disclosure, in the vapor deposition mask 1 having the configuration of aspect 2, the at least one metal remaining portion 12 may be disposed across the at least one first opening in the second direction while dividing the at least one first opening into a plurality of sections.

According to aspect 7 of the disclosure, in the vapor deposition mask 1 having the configuration of aspect 6, the at least one metal remaining portion 12 may have a planoconvex shape.

According to aspect 8 of the disclosure, in the vapor deposition mask 1 having the configuration of aspect 6, the at least one metal remaining portion 12 may have a biconvex shape.

According to aspect 9 of the disclosure, in the vapor deposition mask 1 having the configuration of any one of aspects 2 to 8, at least some of the plurality of second openings may be partially covered with the at least one metal remaining portion 12.

According to aspect 10 of the disclosure, in the vapor deposition mask 1 having the configuration of aspect 9, the plurality of second openings may have a same shape.

According to aspect 11 of the disclosure, in the vapor deposition mask 1 having the configuration of any one of aspects 1 to 8, the plurality of second openings may be formed only in the at least one first opening.

According to aspect 12 of the disclosure, in the vapor deposition mask 1 having the configuration of any one of aspects 1 to 11, the plurality of second openings may be arranged more than one in the first direction.

According to aspect 13 of the disclosure, in the vapor deposition mask 1 having the configuration of any one of aspects 1 to 12, the at least one first opening may include a plurality of first openings, and the plurality of first openings may be arranged in a zig-zag shape.

According to aspect 14 of the disclosure, a vapor deposition apparatus 50 is configured to form a vapor deposition film 72 on a film target substrate 60, the vapor deposition film 72 having a striped pattern. The vapor deposition apparatus includes a vapor deposition unit 52 including: the vapor deposition mask 1 according to any one of aspects 1 to 13 of the disclosure; and a vapor deposition source 30 including at least one vapor deposition source opening 31 configured to emit vapor deposition particles 71, the vapor deposition source 30 being disposed on a side opposite to a side having the film target substrate 60 while interposing the vapor deposition mask 1 between the vapor deposition source 30 and the film target substrate 60. The vapor deposition mask 1 has a length in a first direction shorter than a length of the film target substrate 60 in the first direction. The vapor deposition film 72 is formed on the film target substrate 60 by moving at least one of the film target substrate 60 and the vapor deposition unit 52 in the first direction relative to the other.

According to aspect 15 of the disclosure, in the vapor deposition apparatus 50 having the configuration of aspect 14, the metal mask 10 and the resin mask 20 may be integrated with each other, no alignment marker used in positioning between the metal mask 10 and the resin mask 20 may be provided on the vapor deposition mask 1, and an alignment marker 23 used in positioning between the vapor deposition mask 1 and the film target substrate 60 may be provided on the resin mask 20.

According to aspect 16 of the disclosure, a manufacturing method for a vapor deposition mask 1 including a metal mask 10 and a resin mask 20 in a layered manner, the metal mask 10 including at least one first opening (metal mask opening 11), the resin mask 20 including a plurality of second openings (resin mask openings 21), the plurality of second openings being arranged at least one in a first direction (Y-axial direction) and more than one in a second direction (X-axial direction) orthogonal to the first direction, the second openings exposed from the at least one first opening and aligned in the first direction in respective positions in the second direction having total opening lengths in the first direction, the total opening lengths increasing from a center in the second direction toward both end portions in the second direction, includes: a first opening forming step of forming at least one first opening in a metal plate (metal mask base material 110) provided with a resin film (resin mask base material 120) on one of main surfaces of the metal plate, the at least one first opening penetrating only the metal plate; and a second opening forming step of forming a plurality of second openings in the resin film, the plurality of second openings penetrating only the resin film. The first opening forming step includes forming the at least one first opening having an opening length in the first direction, the opening length increasing toward both end portions in the second direction. The second opening forming step includes forming the plurality of second openings in the resin film from a side having the resin film.

According to aspect 17 of the disclosure, the manufacturing method for the vapor deposition mask 1 having the features of aspect 16 may further include forming the resin film on a surface of the metal plate before the first opening forming step.

According to aspect 18 of the disclosure, a manufacturing method for an electroluminescence display device includes forming a vapor deposition film 72 on a film target substrate 60 by using the vapor deposition apparatus 50 according to aspect 14 or 15 of the disclosure, the vapor deposition film 72 having a striped pattern. The vapor deposition film 72 constitutes a light-emitting layer of the electroluminescence display device. The film target substrate 60 constitutes an electrode substrate of the electroluminescence display device. The light-emitting layer is formed as a film on the electrode substrate.

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

1 Vapor deposition mask
10 Metal mask
11 Metal mask opening (First opening)
11a, 11b Divided metal mask opening
20 Resin mask
21 Resin mask opening (Second opening)
22 Resin mask opening group
23, 62 Alignment marker
30 Vapor deposition source
31 Vapor deposition source opening
40 Limiting plate unit
41 Limiting plate
42 Limiting plate opening
43 Scanning direction limiting plate
50 Vapor deposition apparatus
51 Vapor deposition block
52 Vapor deposition unit
60 Film target substrate (Electrode substrate)
71 Vapor deposition particle
72 Vapor deposition film (Light-emitting layer)
101 Compound mask base material
110 Metal mask base material (Metal plate)
120 Resin mask base material (Resin film)

1: A vapor deposition mask comprising:
a metal mask; and
a resin mask, the metal mask and the resin mask being layered,
wherein the metal mask includes at least one first opening,
the at least one first opening has an opening length in a first direction, the opening length increasing from a center in a second direction toward both end portions in the second direction, the second direction being orthogonal to the first direction,
the resin mask includes a plurality of second openings,
the plurality of second openings are arranged at least one in the first direction and more than one in the second direction, and
the second openings exposed from the at least one first opening and aligned in the first direction in respective positions in the second direction have total opening lengths in the first direction, the total opening lengths increasing from the center in the second direction toward both end portions in the second direction.

2: The vapor deposition mask according to claim 1,
wherein the metal mask includes at least one metal remaining portion having a length in the first direction, the length decreasing from the center in the second direction toward both end portions in the second direction.

3: The vapor deposition mask according to claim 2,
wherein the at least one metal remaining portion is disposed at at least one of end portions of the at least one first opening in the first direction.

4: The vapor deposition mask according to claim 2,
wherein the at least one metal remaining portion includes a plurality of metal remaining portions, and
the plurality of metal remaining portions are disposed at both end portions of the at least one first opening in the first direction.

5: The vapor deposition mask according to claim 2,
wherein the at least one metal remaining portion is disposed at only one of end portions of the at least one first opening in the first direction.

6: The vapor deposition mask according to claim 2,
wherein the at least one metal remaining portion is disposed across the at least one first opening in the second direction while dividing the at least one first opening into a plurality of sections.

7: The vapor deposition mask according to claim 6,
wherein the at least one metal remaining portion has a planoconvex shape.

8: The vapor deposition mask according to claim 6,
wherein the at least one metal remaining portion has a biconvex shape.

9: The vapor deposition mask according to claim 2,
wherein at least some of the plurality of second openings are partially covered with the at least one metal remaining portion.

10: The vapor deposition mask according to claim 9,
wherein the plurality of second openings have a same shape.

11: The vapor deposition mask according to claim 1,
wherein the plurality of second openings are formed only in the at least one first opening.

12: The vapor deposition mask according to claim 1,
wherein the plurality of second openings are arranged more than one in the first direction.

13: The vapor deposition mask according to claim 1,
wherein the at least one first opening includes a plurality of first openings, and
the plurality of first openings are arranged in a zig-zag shape.

14: A vapor deposition apparatus configured to form a vapor deposition film on a film target substrate, the vapor deposition film having a striped pattern, the vapor deposition apparatus comprising:
a vapor deposition unit including:
the vapor deposition mask according to claim 1; and
a vapor deposition source including at least one vapor deposition source opening configured to emit vapor deposition particles, the vapor deposition source being disposed on a side opposite to a side having the film target substrate while interposing the vapor deposition mask between the vapor deposition source and the film target substrate,
wherein the vapor deposition mask has a length in a first direction shorter than a length of the film target substrate in the first direction, and
the vapor deposition film is formed on the film target substrate by moving at least one of the film target substrate and the vapor deposition unit in the first direction relative to the other.

15: The vapor deposition apparatus according to claim 14,
wherein the metal mask and the resin mask are integrated with each other,
no alignment marker used in positioning between the metal mask and the resin mask is provided on the vapor deposition mask, and
an alignment marker used in positioning between the vapor deposition mask and the film target substrate is provided on the resin mask.

16: A manufacturing method for a vapor deposition mask including a metal mask and a resin mask in a layered manner, the metal mask including at least one first opening, the resin mask including a plurality of second openings, the plurality of second openings being arranged at least one in a first direction and more than one in a second direction orthogonal to the first direction, the second openings exposed from the at least one first opening and aligned in the first direction in respective positions in the second direction having total opening lengths in the first direction, the total opening lengths increasing from a center in the second direction toward both end portions in the second direction, the method comprising:
a first opening forming step of forming at least one first opening in a metal plate provided with a resin film on one of main surfaces of the metal plate, the at least one first opening penetrating only the metal plate; and
a second opening forming step of forming a plurality of second openings in the resin film, the plurality of second openings penetrating only the resin film,
wherein the first opening forming step includes forming the at least one first opening having an opening length in the first direction, the opening length increasing from the center in the second direction toward both end portions in the second direction, and
the second opening forming step includes forming the plurality of second openings in the resin film from a side having the resin film.

17: The manufacturing method for the vapor deposition mask according to claim 16,
wherein the method further includes forming the resin film on a surface of the metal plate in an integrated manner before the first opening forming step.

18: A manufacturing method for an electroluminescence display device, comprising:
forming a vapor deposition film on a film target substrate by using the vapor deposition apparatus according to claim 14, the vapor deposition film having a striped pattern,
wherein the vapor deposition film constitutes a light-emitting layer of the electroluminescence display device,
the film target substrate constitutes an electrode substrate of the electroluminescence display device, and
the light-emitting layer is formed as a film on the electrode substrate.
